(19) United States
(12) Patent Application Publication
(10) Pub. No.: US 2017/0301276 A1
(43) Pub. Date: Oct. 19, 2017

(54) SHIFT REGISTER UNIT AND DRIVING METHOD THEREOF, ROW SCANNING DRIVING CIRCUIT AND DISPLAY DEVICE

(71) Applicant: BOE TECHNOLOGY GROUP CO., LTD., Beijing (CN)

(72) Inventors: Min HE, Beijing (CN); Guangcai YUAN, Beijing (CN); Wenchao BAO, Beijing (CN)

(21) Appl. No.: 15/323,490

(22) PCT Filed: Feb. 25, 2016
(86) PCT No.: PCT/CN2016/074538

§ 371 Date: Jan. 3, 2017

(30) Foreign Application Priority Data
Sep. 21, 2015 (CN) 201510605123.2

(51) Int. Cl. G09G 3/20; G11C 19/28

(52) U.S. Cl. CPC G09G 3/2092; G11C 19/28; G09G 2300/0408; G09G 2310/0286; G09G 2310/08; G09G 2310/0291

(57) ABSTRACT

Embodiments of the present disclosure provide a shift register unit and a driving method thereof, a row scanning driving circuit and a display device. The shift register unit includes an input terminal, a reset terminal, and an output terminal, and further includes an input module configured to pull up the electric level at the first node, an output module configured to pull up the electric level at the output terminal, a reset module configured to pull down the electric level at the first node, and a first pull-down module configured to pull down the electric level at the output terminal. Embodiments of the present disclosure can solve the problem that the floating state of the row scanning driving circuit affects the output stability.

### CROSS REFERENCE TO RELATED APPLICATIONS

This application is a National Stage entry of PCT/CN2016/074538 filed Feb. 25, 2016, which claims the benefit and priority of Chinese Patent Application No. 201510605123.2, filed on Sep. 21, 2015, the disclosures of which are incorporated herein in their entirety as part of the present application.

### BACKGROUND

The present disclosure relates to the field of display technology, and particularly, to a shift register unit and a driving method thereof, a row scanning driving circuit and a display device.

Gate driver On Array (GOA) technology represents a new technology which integrates a row scanning driving circuit on an array substrate to remove a conventional row scanning driving integrated circuit, so as to save material and reduce manufacturing steps, and to achieve the purpose of reducing product costs. However, in the conventional row scanning driving circuit, the output terminal for a row scanning signal is in a floating state in a large part of the circuit timing. In this state, a row scanning signal outputted by GOA is easy to be affected by coupling other signals, and hence unstable, thus affecting the output performance of the row scanning driving circuit.

### BRIEF DESCRIPTION

Embodiments of the present disclosure provide a shift register unit and a driving method thereof, a row scanning driving circuit and a display device, which can solve the problem that the floating state of a row scanning signal output terminal affects the output stability in the row scanning driving circuit.

According to a first aspect, the embodiments of the present disclosure provide a shift register unit including an input terminal, a reset terminal, and an output terminal, further including an input module, which is connected to the input terminal and a first node, and is configured to pull up the electric level at the first node when the input terminal is at a valid electric level, an output module, which is connected to the first node and the output terminal, and is configured to pull up the electric level at the output terminal based on a first clock signal when the first node is at a high electric level, a reset module, which is connected to the reset terminal and the first node, and is configured to pull down the electric level at the first node when the reset terminal is at a valid electric level, and a first pull-down module, which is connected to the output terminal, includes a control terminal, and is configured to pull down the electric level at the output terminal when the control terminal is at a valid electric level.

In embodiments of the present disclosure, the control terminal is connected to the first node and the valid electric level of the control terminal is a low electric level.

In embodiments of the present disclosure, the input module includes a first transistor, a gate of the first transistor is connected to the input terminal, one of a source and a drain of the transistor is connected to the input terminal and the other is connected to the first node.

In embodiments of the present disclosure, the reset module includes a second transistor, a gate of the second transistor is connected to the reset terminal, one of a source and a drain of the second transistor is connected to the first node and the other is connected to a low-level voltage line.

In embodiments of the present disclosure, the output module includes a third transistor and a first capacitor, wherein, a gate of the third transistor is connected to the first node, one of a source and a drain of the third transistor is connected to a first clock signal terminal supplying a first clock signal, and the other is connected to the output terminal. A first terminal of the first capacitor is connected to the first node and the second terminal of the first capacitor is connected to the output terminal.

In embodiments of the present disclosure, the first pull-down module includes a fourth transistor, a gate of the fourth transistor is connected to the control terminal of the first pull-down module, one of a source and a drain of the fourth transistor is connected to the output terminal, and the other is connected to a low-level voltage line.

In embodiments of the present disclosure, a second capacitor is also included. The first terminal of the second capacitor is connected to a second clock signal terminal, and the second terminal of the second capacitor is connected to the first node.

In embodiments of the present disclosure, the shift register unit further includes a second pull-down module, the second pull-down module is connected to the input terminal and the output terminal, and is configured to pull down the electric level at the output terminal when the input terminal is at a valid electric level.

In embodiments of the present disclosure, the second pull-down module includes a fifth transistor, a gate of the fifth transistor is connected to the input terminal, one of a source and a drain of the fifth transistor is connected to the output terminal, and the other is connected to a low-level voltage line.

In embodiments of the present disclosure, the shift register unit further includes a third pull-down module, the third pull-down module is connected to the reset terminal and the output terminal, and is configured to pull down the electric level at the output terminal when the reset terminal is at a valid electric level.

In embodiments of the present disclosure, the third pull-down module includes a sixth transistor, a gate of the sixth transistor is connected to the reset terminal, one of a source and a drain of the sixth transistor is connected to the output terminal and the other is connected to a low-level voltage line.

According to a second aspect, the embodiments of the present disclosure also provide a row scanning driving circuit including a plurality of cascaded shift register units of any of the foregoing.

According to a third aspect, the embodiments of the present disclosure also provide a display device including any one of the above-described row scanning driving circuits.

According to a fourth aspect, the embodiments of the present disclosure also provide a driving method for any one of the shift register units, including a first phase making a first clock signal at a low electric level, connecting an input terminal to a valid electric level, connecting a reset terminal to an invalid electric level, pulling up the electric level at a first node by the input module, and making an output terminal at a low electric level. A second phase making the first clock signal at a high electric level, connecting the input terminal to an invalid electric level, connecting the reset terminal to an invalid electric level, pulling up the electric level at the output terminal by the output module based on the first clock signal. A third phase making the first clock signal at a low electric level, connecting the input terminal to an invalid electric level, connecting the reset terminal to a valid electric level, pulling down the electric level at the first node by the reset module, and making the output terminal at a low electric level.

In embodiments of the disclosure, with the setting of the first pull-down module, the electric level at the output terminal is pulled down when the first node is at a valid electric level, or the electric level at the output terminal may be pulled down under the control of an external control signal, such that the floating connection at the output terminal can be effectively avoided during this period, and the output signal is protected against effects from the other portion of the circuit, thereby ensuring the high stability of signal output.

### BRIEF DESCRIPTION OF THE DRAWINGS

In order to more clearly illustrate the technical solutions in the embodiments of the present disclosure or in the prior art, the accompanying drawings which are required to be used in the description of the embodiments will be described below in brief. It will be apparent that the drawings in the following description are merely about some embodiments of the present disclosure. Those skilled in the art may also obtain other drawings from these drawings without creative work.

FIG. 1 is a block diagram of the structure of a shift register unit according to embodiments of the present disclosure;

FIG. 2 is a first schematic circuit structure diagram of the shift register unit of FIG. 1;

FIG. 3 is a circuit timing diagram of the shift register unit shown in FIG. 2;

FIG. 4 is a second schematic circuit structure diagram of the shift register unit of FIG. 1; and

FIG. 5 is a third schematic circuit structure diagram of the shift register unit of FIG. 1.

### DETAILED DESCRIPTION

In order to make the technical solutions and advantages of the embodiments of the present disclosure clearer, the technical solutions of the embodiments of the present disclosure will be clearly and completely described below in conjunction with the accompanying drawings in the embodiments of the present disclosure. The embodiments described are merely part of instead of all the embodiments of the present disclosure. All other embodiments obtained by those skilled in the art based on the embodiments of the present disclosure without creative effort are within the scope of the present disclosure.

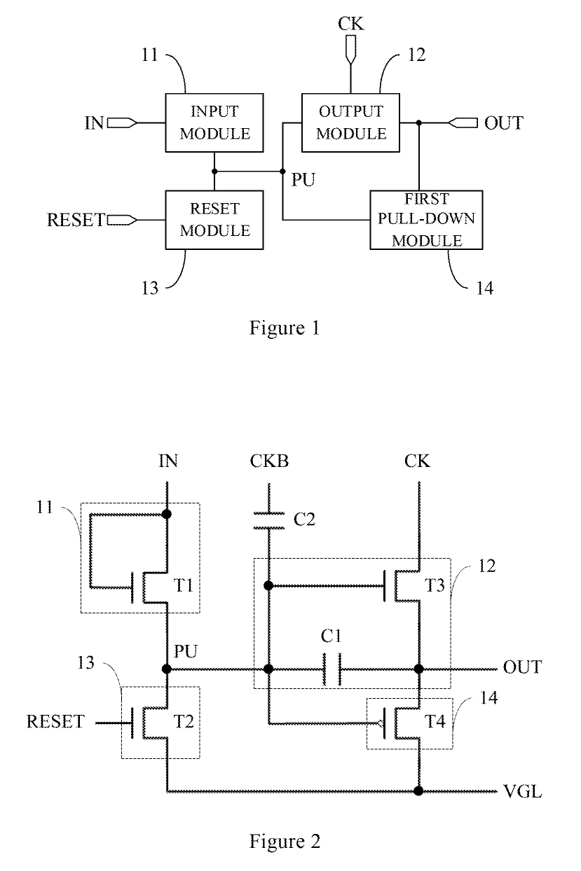

FIG. 1 is a block diagram of the structure of a shift register unit according to embodiments of the present disclosure. See FIG. 1, the shift register unit includes an input terminal IN, a reset terminal RESET, and an output terminal OUT, further includes an input module 11, which is connected to the input terminal IN and a first node PU, and is configured to pull up the electric level at the first node PU when the input terminal IN is at a valid electric level, an output module 12, which is connected to the first node PU and the output terminal OUT, and is configured to pull up the electric level at the output terminal OUT based on a first clock signal CK when the first node PU is at a high electric level, a reset module 13, which is connected to the reset terminal RESET and the first node PU, and is configured to pull down the electric level at the first node PU when the reset terminal RESET is at a valid electric level, and a first pull-down module 14, which is connected to the output terminal OUT. The first pull-down module 14 includes a control terminal and is configured to pull down the electric level at the output terminal OUT when the control terminal is at a valid electric level.

In the embodiments of the present disclosure, the control terminal may be connected to the first node PU, and the valid electric level of the control terminal may be low. The control terminal can also be connected to an external control signal. The advantage of connecting the control node to the first node PU is that the number of external signals required can be reduced.

It should be noted that “high electric level” and “low electric level” herein refer to two logic states represented by electric level amplitude ranges at a certain circuit node location. For example, the high electric level at the first node PU may refer specifically to a level higher than the common terminal voltage by 3V or more, and the low electric level at the first node PU may refer specifically to a level lower than the common terminal voltage by 3V or more, while the high electric level at the output terminal OUT may refer specifically to a level higher than the common terminal voltage by 6V or more and the low electric level at the output terminal OUT may refer specifically to a level lower than the common terminal voltage by 6V or more. It is to be understood that a specific electric level amplitude range may be set as desired in a particular application circumstance, and the present disclosure does not limit that.

Correspondingly, “pulling up” herein refers to raising the electric level at the corresponding circuit node to a high electric level, and “pulling down” herein refers to pulling down the electric level at the corresponding circuit node to a low electric level. It is to be understood that both the above-mentioned “pulling up” and “pulling down” can be achieved by a directional movement of the electric charge, and thus can be achieved specifically by electronic components or a combination thereof having a corresponding function, while the present disclosure does not limit it.

Further, the terms “valid electric level” and “invalid electric level” herein refer to two mutually non-intersecting electric level amplitude ranges at a certain circuit node position, for example, respectively being one of high electric level or low electric level, while the present disclosure does not limit it.

The operation principle of the shift register unit will be described below in order to more clearly explain the structure and function of each of the above-described modules.

In general, both the input terminal IN and the reset terminal RESET are at the invalid electric level, while the first node PU remains low. The output terminal OUT is also kept at the low electric level by the pull-down action of the first pull-down module 14. Thereafter, the input terminal IN changes from the invalid electric level to the valid electric level, and the first clock signal CK is at the low electric level. The input module 11 may pull up the electric level at the first node PU to a high electric level, the first pull-down module 14 stops pulling down the electric level at the output terminal OUT, and the output module 12 may output to the output terminal a low electric level from the first clock signal CK. Thereafter, the first clock signal CK goes to the high electric level, and the output module 12 uses the high electric level of the first clock signal CK to pull up the output terminal OUT to a high electric level. Finally, the reset terminal RESET changes from the invalid electric level to the valid electric level, the reset module 13 can pull down the electric level at the first node PU to the low electric level, and the output module 12 stops pulling up the electric level at the output terminal OUT. Also, after the first node PU is pulled down to the low electric level, the first pull-down module 14 resumes pulling down the electric level at the output terminal OUT so that the output terminal OUT remains at the low electric level.

The embodiments of the present disclosure pulls down the electric level at the output terminal OUT based on the setting of the first pull-down module 14. The first pull-down module 14 may pull down the electric level at the output terminal OUT when the first node PU is at the low electric level or pull down the electric level at the output terminal OUT under the control of an external control signal, thereby effectively preventing the output terminal OUT from being floating. When the control terminal of the first pull-down module 14 is not connected to the first node PU but is connected to an external control signal, the external control signal may cooperate with the electric level at the output terminal OUT in timing, e.g., the external control signal may apply a valid electric level at the control terminal of the first pull-down module 14 during all the time when the output terminal OUT is not set at a high electric level, to prevent the output terminal OUT from being floating. In either way, the output terminal OUT is substantially not in the floating state during the operation of the shift register unit, and therefore, the embodiments of the present disclosure can prevent the output signal of the shift register unit from being affected by other parts of the circuit, thereby ensuring high stability of the signal output.

FIG. 2 is a first schematic circuit structure diagram of the shift register unit of FIG. 1. As shown in FIG. 2, in the embodiments of the present disclosure, the input module 11 includes a first transistor T1, a gate of the first transistor T1 is connected to the input terminal IN, one of a source and a drain of the first transistor T1 is connected to the input terminal IN, and the other is connected to the first node PU. Thus, when the input terminal IN is at a high electric level, a current flowing from the input terminal IN to the first node PU can be formed inside the first transistor T1 to achieve the pull-up of the first node PU. The embodiments of the present disclosure can achieve the function of the above-mentioned input module 11 through a transistor.

It should be noted that the first transistor T1 shown in FIG. 2 is an N-type transistor (the source and drain thereof are connected when the gate is at a high electric level), and therefore the valid electric level at the input terminal IN is high. In other embodiments of the present disclosure, the first transistor T1 may be replaced by a P-type transistor (the source and drain thereof are connected when the gate is at a low electric level, and the valid electric level at the input terminal IN is low), while the present disclosure does not limit it. In addition, the connection manner of the source and the drain of the transistor can be determined according to the type of the selected transistor. It is well known to those skilled in the art that the source and the drain can be regarded as two electrodes which need not to be particularly distinguished when the transistor has a symmetrical structure of the source and the drain, which will not be further described herein.

In the embodiments of the present disclosure, the reset module 13 includes a second transistor T2, a gate of the second transistor T2 is connected to the reset terminal RESET, one of a source and a drain of the second transistor T2 is connected to the first node PU, and the other is connected to a low-level voltage line VGL. Thus, when the reset terminal RESET is at a high, valid electric level, a current flowing from the first node PU to the low-level voltage line VGL can be formed inside the second transistor T2 to achieve the pull-down of the first node PU. The embodiments of the present disclosure can achieve the function of the reset module 13 described above through a transistor.

In embodiments of the present disclosure, the output module 12 includes a third transistor T3 and a first capacitor C1, a gate of the third transistor T3 is connected to the first node PU, one of a source and a drain of the third transistor T3 is connected to the first clock signal terminal CK providing a first clock signal, and the other is connected to the output terminal OUT. The first terminal of the first capacitor C1 is connected to the first node PU, and the second terminal of the first capacitor C1 is connected to the output terminal OUT. Thus, when the first node PU is at the high electric level and the first clock signal CK is at the low electric level, the output terminal OUT is at the low electric level, while at this time, the first capacitor C1 has an electric level difference between two ends and stores a certain amount of electric charge. When the electric level at the first clock signal CK changes from the low electric level to the high electric level, the electric level at the output terminal OUT will be pulled up by the current from the first clock signal CK. Since the voltage difference across the first capacitor C1 won't change, whereby the electric level at the first node PU will be further raised by the action of the first capacitor C1, increasing the speed at which the electric level at the output terminal OUT is pulled up. The embodiments of the present disclosure can achieve the functions of the output module 12 described above through a transistor and a capacitor.

In the embodiments of the present disclosure, the first pull-down module 14 includes a fourth transistor T4, a gate of the fourth transistor T4 is connected to the first node PU, one of a source and a drain of the fourth transistor T4 is connected to the output terminal OUT, and the other is connected to the low-level voltage line VGL. Thus, when the fourth transistor T4 is a P-type transistor, the low electric level at the first node PU can cause a current flowing from the output terminal OUT to the low-level voltage line VGL to be formed in the fourth transistor T4 to achieve the pull-down of the output terminal OUT. The embodiments of the present disclosure may achieve the function of the first pull-down module 14 described above through a transistor.

In addition, the shift register unit of the present disclosure further includes a second capacitor C2. The first terminal of the second capacitor C2 is connected to a second clock signal terminal CKB which provides a second clock signal, and the second terminal of the second capacitor C2 is connected to the first node PU. It should be noted that the first clock signal and the second clock signal are a pair of clock signals including a positive phase clock signal and an inverted phase clock signal, wherein the positive phase clock signal and the inverted phase clock signal may be from external inputs. The second capacitor C2 may filter out the noise at the first node PU and stabilize the electric level at the first node PU.

It will be appreciated that either the high or low electric level at any of the circuit nodes may be provided by a corresponding bias voltage line or other circuit node, e.g., the terminal of the first transistor T1 which is connected to the input terminal IN may also be changed to be connected to a high-level bias voltage line, the terminal of the second transistor T2 which is connected to the low-level voltage line VGL may be changed to be connected to the reset terminal RESET (at the time, the second transistor T2 is changed to a P-type transistor, and the valid electric level changes to a low electric level), etc., which all belong to the equivalent replacements of the circuit structure, and the present disclosure does not limit it.

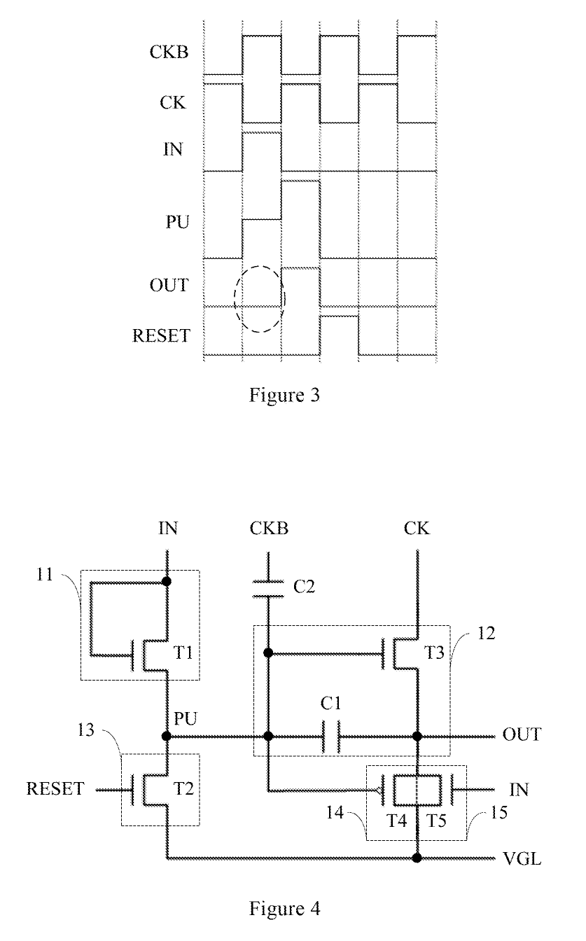

FIG. 3 is a circuit timing diagram of the shift register unit shown in FIG. 2. As shown in FIG. 3, the driving method for the shift register unit includes a first phase making a first clock signal at a low electric level, connecting the input terminal IN to a valid electric level, connecting the reset terminal RESET to an invalid electric level, pulling up the electric level at the first node PU by the input module 11, and making the output terminal OUT at a low electric level. A second phase making the first clock signal at a high electric level, connecting the input terminal IN to an invalid electric level, connecting the reset terminal to an invalid electric level, pulling up the electric level at the output terminal OUT by the output module 12 based on the first clock signal. A third phase making the first clock signal at a low electric level, connecting the input terminal IN to an invalid electric level, connecting the reset terminal RESET to a valid electric level, pulling down the electric level at the first node PU by the reset module 13, and making the output terminal OUT at a low electric level.

However, it should be noted that at the location marked by the dashed circle in FIG. 3, the output terminal OUT will be in a floating state for a short period. Specifically, when the signal at the input terminal IN changes from the low electric level to the high electric level, there is a period for the electric level at the first node PU changing from the low electric level to the high electric level under the action of maintaining electric level by the first capacitor C1. At the beginning of this phase, the fourth transistor T4 will immediately stop the pull-down of the electric level at the output terminal OUT, but the third transistor T3 will not be immediately turned on. Thus, the output terminal OUT is actually in a floating state for a short period after the fourth transistor T4 is turned off and before the third transistor T3 is turned on.

In order to solve the floating problem at the above-mentioned output terminal OUT, it is also possible to add a second pull-down module 15 on the basis of the structure of the shift register unit shown in FIG. 2.

FIG. 4 is a second schematic circuit structure diagram of the shift register unit of FIG. 1. See FIG. 4, the embodiments of the present disclosure is added with a second pull-down module 15 on the basis of the shift register unit shown in FIG. 2, for pulling down the electric level at the output terminal OUT when the input terminal IN is at a valid electric level. Thus, during the period when the input terminal IN is at high electric level, the second pull-down module 15 can keep the electric level at the output terminal OUT low, to prevent the output terminal OUT from being floating within the period before the third transistor T3 is turned on. As a specific example, the second pull-down module 15 may include a fifth transistor T5, a gate of the fifth transistor T5 is connected to the input terminal IN, one of a source and a drain of the fifth transistor T5 is connected to the output terminal OUT, and the other is connected to the low-level voltage line VGL. Thus, the above described function of the second pull-down module 15 can be achieved by a transistor.

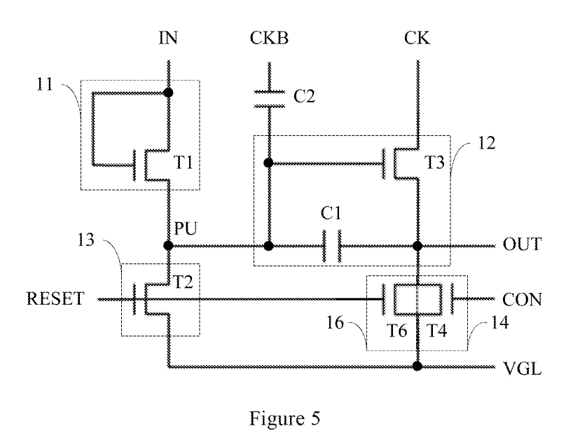

FIG. 5 is a third schematic circuit structure diagram of the shift register unit of FIG. 1. See FIG. 5, differing from the shift register unit shown in FIG. 2, the shift register unit of the embodiments of the present disclosure includes a third pull-down module 16, and the control terminal of the first pull-down module 14 is connected to the external control signal CON described above instead of the first node PU. The third pull-down module 16 is used to pull down the electric level at the output terminal OUT when the reset terminal RESET is at the valid electric level, so that the electric level at the output terminal OUT can be pulled low for a period during which the reset terminal RESET is at the high electric level. As a specific example, the third pull-down module 16 may include a sixth transistor T6, a gate of the sixth transistor T6 is connected to the reset terminal RESET, one of a source and a drain of the sixth transistor T6 is connected to the output terminal OUT, and the other is connected to the low-level voltage line VGL. This makes it possible to achieve the function of the third pull-down module 16 described above.

It is to be understood that the third pull-down module 16 may complete the pull-down of the electric level at the output terminal OUT under the action of the signal to which the reset terminal RESET is connected. But in the shift register unit including only the third pull-down module 16, the output terminal OUT will still be floating, for example, within the period after the signal connected to the reset terminal RESET changes to the invalid electric level. The above-mentioned external control signal CON may provide a valid electric level to the control terminal of the first pull-down module 14 all the time except that the output terminal OUT is set to a high electric level, to prevent the output terminal OUT from being floating within any period. Of course, the external control signal CON may be at an invalid electric level when the output terminal OUT would not be in the floating state. For example, the external control signal CON in the embodiments of the present disclosure may also be at the invalid electric level during the period when the reset terminal RESET is at the valid electric level, since the third pull-down module 16 may prevent the output terminal OUT from being floating during this period.

It should be noted that the first pull-down module 14, the second pull-down module 15, and the third pull-down module 16 of any one of the above-described structures are used to pull down the electric level at the output terminal OUT for a certain period of time, and there is no functional conflict therebetween, so one or more of these can be selected by a person skilled in the art to be placed in a shift register unit, and the present disclosure does not limit it.

Based on the same disclosure concept, embodiments of the present disclosure provide a row scanning driving circuit including multi-stage shift register units, the shift register unit at each stage having a circuit structure of any one of the shift register units described above. The shift register unit is configured to output a row scanning driving signal for the corresponding one row of pixel units. In one embodiments of the present disclosure, the above-described multi-stage shift register units can also be connected in such a manner that the input terminal of the shift register units at any stage, except at the first stage, is connected to the output terminal of the shift register unit at the preceding stage and the output terminal of the shift register units at any stage, except at the first stage, is connected to the reset terminal of the shift register unit at the preceding stage. It will be appreciated that the row scanning driving circuit can achieve step-wise signal transfer and output with the advantages of any of the shift register units described above.

Based on the same disclosure concept, embodiments of the present disclosure provide a display device including_a row scanning driving circuit of any one of the above. For example, the row scanning driving circuit may be provided outside the display area on the array substrate of the display device to form a GOA circuit structure. Thus, the display device includes any one of the above-mentioned row scanning driving circuits, and therefore has the advantages of any of the above-described array substrates. It should be noted that the display device in the present embodiment may be any product or component having a display function such as an electronic paper, a mobile phone, a tablet computer, a television set, a notebook computer, a digital photo frame, a navigator or the like.

In the description of the present disclosure, it is to be noted that the orientation or positional relationship indicated by the terms “up”, “low” and the like is based on the orientation or positional relationship shown in the drawings only for the convenience and simplification of description for the disclosure, not intended to indicate or hint that the referenced device or element must be of a particular orientation, constructed and operated in a particular orientation, and therefore should not be explained as limitation to the disclosure. The terms “install”, “connect”, “attach” shall be understood broadly, unless otherwise explicitly specified and defined, for example, as a fixed connection, a detachable connection, an integral connection, a mechanical connection, an electrical connection, a direct connection, an indirect connection through an intermediate medium or an internal connection between two components. It will be apparent to those skilled in the art to understand the specific meaning of the above-mentioned terms in the present disclosure based on the specific circumstance.

In the description of the present disclosure, numerous specific details are set forth. It will be understood, however, that the embodiments of the disclosure may be practiced without these specific details. In some instances, well-known methods, structures, and techniques have not been shown in detail in order not to obscure the understanding of this specification.

Similarly, it will be understood that in order to simplify the disclosure and facilitate the understanding of one or more of the various inventive aspects, in the above description of exemplary embodiments of the disclosure, various features of the disclosure are sometimes grouped together into a single embodiment, a graph, or a description thereof. However, the manner of the disclosure should not be interpreted as reflecting the intention that the claimed disclosure requires more features than expressly recited in each claim. Rather, as reflected in the claims, the inventive aspects has less features than those of the previously disclosed individual embodiments. Accordingly, the claims following the detailed embodiments hereby are expressly incorporated in the detailed embodiments therein, each claim itself as a separate embodiment of the present disclosure.

It is to be noted that the above-described embodiments illustrate instead of limiting the present disclosure, and those skilled in the art may devise alternative embodiments without departing from the scope of the appended claims. In the claims, any reference sign placed within parentheses shall not be construed as limiting the claim. The word “including” does not exclude the presence of elements or steps that are not listed in the claims. The word “a” or “one” preceding an element does not exclude the presence of a plurality of such elements. The disclosure may be implemented by means of hardware including several distinct elements and by means of a suitably programmed computer. In a unit claim listing several means, some of these means may be specifically embodied by the same item of hardware. The use of the words first, second, and third does not denote any order. These words can be interpreted as names.

Finally, it should be noted that the above embodiments are merely illustrative of the technical solutions of the present disclosure and are not to be construed as limitations thereof. Although the disclosure has been described in detail with reference to the foregoing embodiments, it will be understood by those skilled in the art that they can still modify the technical solutions described in the foregoing embodiments or equivalently replace some or all of the technical features therein, and these modifications or substitutions do not depart the essence of the corresponding technical solutions from the scope of the technical solutions of the embodiments of the present disclosure, and should be encompassed within the scope of the claims and the description of the present disclosure.

What is claimed is:

1. A shift register unit comprising an input terminal, a reset terminal, and an output terminal, further comprising:
an input module connected to the input terminal and a first node, and configured to pull up the electric level at the first node when the input terminal is at a valid electric level;
an output module connected to the first node and the output terminal, and configured to pull up the electric level at the output terminal based on a first clock signal when the first node is at a high electric level;
a reset module connected to the reset terminal and the first node, and is configured to pull down the electric level at the first node when the reset terminal is at a valid electric level; and
a first pull-down module connected to the output terminal, comprises a control terminal, and is configured to pull down the electric level at the output terminal when the control terminal is at a valid electric level.

2. The shift register unit according to claim 1, wherein the control terminal is connected to the first node and the valid electric level of the control terminal is a low electric level.

3. The shift register unit according to claim 1, wherein the input module comprises a first transistor, wherein a gate of the first transistor is connected to the input terminal, and wherein one of a source and a drain of the first transistor is connected to the input terminal and the other of the source and the drain is connected to the first node.

4. The shift register unit according to claim 1, wherein the reset module comprises a second transistor, wherein a gate of the second transistor is connected to the reset terminal, and wherein one of a source and a drain of the second transistor is connected to the first node and the other of the source and the drain is connected to a low-level voltage line.

5. The shift register unit according to claim 1, wherein the output module comprises:
a third transistor and a first capacitor;
wherein a gate of the third transistor is connected to the first node, wherein one of a source and a drain of the third transistor is connected to a first clock signal terminal supplying the first clock signal, wherein the other of the source and the drain is connected to the output terminal, and wherein a first terminal of the first capacitor is connected to the first node and a second terminal of the first capacitor is connected to the output terminal.

6. The shift register unit according to claim 1, wherein the first pull-down module comprises a fourth transistor, wherein a gate of the fourth transistor is connected to the control terminal of the first pull-down module, wherein one of a source and a drain of the fourth transistor is connected to the output terminal, and wherein the other of the source and the drain is connected to a low-level voltage line.

7. The shift register unit according to claim 1, further comprising a second capacitor, wherein the first terminal of the second capacitor is connected to a second clock signal terminal, and wherein the second terminal of the second capacitor is connected to the first node.

8. The shift register unit according to claim 1, further comprising a second pull-down module, wherein the second pull-down module is connected to the input terminal and the output terminal, and is configured to pull down the electric level at the output terminal when the input terminal is at a valid electric level.

9. The shift register unit according to claim 8, wherein the second pull-down module comprises a fifth transistor, wherein a gate of the fifth transistor is connected to the input terminal, wherein one of a source and a drain of the fifth transistor is connected to the output terminal, and wherein the other of the source and the drain is connected to a low-level voltage line.

10. The shift register unit according to claim 1, further comprising a third pull-down module, wherein the third pull-down module is connected to the reset terminal and the output terminal, and is configured to pull down the electric level at the output terminal when the reset terminal is at a valid electric level.

11. The shift register unit according to claim 10, wherein the third pull-down module comprises a sixth transistor, wherein a gate of the sixth transistor is connected to the reset terminal, and wherein one of a source and a drain of the sixth transistor is connected to the output terminal and the other of the source and the drain is connected to a low-level voltage line.

12. A row scanning driving circuit, comprising a plurality of cascaded shift register units of claim 1.

13. A display device, comprising the row scanning driving circuit of claim 12.

14. A driving method for the shift register unit of claim 1, comprising:
a first phase comprising making the first clock signal at a low electric level, connecting the input terminal to a valid electric level, connecting the reset terminal to an invalid electric level, pulling up the electric level at the first node by the input module, and making the output terminal at a low electric level;
a second phase comprising making the first clock signal at a high electric level, connecting the input terminal to an invalid electric level, connecting the reset terminal to an invalid electric level, pulling up the electric level at the output terminal by the output module based on the first clock signal, and making the output terminal at a high electric level; and
a third phase comprising making the first clock signal at a low electric level, connecting the input terminal to an invalid electric level, connecting the reset terminal to a valid electric level, pulling down the electric level at the first node by the reset module, and making the output terminal at a low electric level.

15. The shift register unit according to claim 2, further comprising a second pull-down module, wherein the second pull-down module is connected to the input terminal and the output terminal, and is configured to pull down the electric level at the output terminal when the input terminal is at a valid electric level.

16. The shift register unit according to claim 3, further comprising a second pull-down module, wherein the second pull-down module is connected to the input terminal and the output terminal, and is configured to pull down the electric level at the output terminal when the input terminal is at a valid electric level.

17. The shift register unit according to claim 4, further comprising a second pull-down module, wherein the second pull-down module is connected to the input terminal and the output terminal, and is configured to pull down the electric level at the output terminal when the input terminal is at a valid electric level.

18. The shift register unit according to claim 5, further comprising a second pull-down module, wherein the second pull-down module is connected to the input terminal and the output terminal, and is configured to pull down the electric level at the output terminal when the input terminal is at a valid electric level.

19. The shift register unit according to claim 6, further comprising a second pull-down module, wherein the second pull-down module is connected to the input terminal and the output terminal, and is configured to pull down the electric level at the output terminal when the input terminal is at a valid electric level.

20. The shift register unit according to claim 7, further comprising a second pull-down module, wherein the second pull-down module is connected to the input terminal and the output terminal, and is configured to pull down the electric level at the output terminal when the input terminal is at a valid electric level.
